(19) United States
(12) Patent Application Publication
(10) Pub. No.: US 2007/0069264 A1
(43) Pub. Date: Mar. 29, 2007

(54) Ferroelectric varactors suitable for capacitive shunt switching and wireless sensing

(76) Inventors: Guru Subramanyam, Dayton, OH (US); Andre Vorobiev, Gothenburg (SE); Spartak Gevorgian, Gothenburg (SE)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/543,654

(22) Filed: Oct. 5, 2006

Related U.S. Application Data
(63) Continuation-in-part of application No. PCT/US04/34266, filed on Oct. 15, 2004.
(60) Provisional application No. 60/512,631, filed on Oct. 20, 2003.

(51) Int. Cl. H01L 29/94

(52) U.S. Cl. 257/295; 342/51; 257/312; 438/379; 257/E29.344

(57) ABSTRACT

A ferroelectric varactor suitable for capacitive shunt switching is disclosed. High resistivity silicon with a SiO₂ layer and a patterned metallic layer deposited on top is used as the substrate. A ferroelectric thin-film layer deposited on the substrate is used for the implementation of the varactor. A top metal electrode is deposited on the ferroelectric thin-film layer forming a CPW transmission line. By using the capacitance formed by the large area ground conductors in the top metal electrode and bottom metallic layer, a series connection of the ferroelectric varactor with the large capacitor defined by the ground conductors is created. The large capacitor acts as a short to ground, eliminating the need for vias. In one embodiment, the varactor shunt switch can be used as passive sensor with the capability of being wireless.

### CROSS-REFERENCE TO RELATED APPLICATIONS

This application is a continuation-in-part of PCT Application US 2004/034266, filed Oct. 15, 2004, which claims the benefit of U.S. Provisional Application Ser. No. 60/512,631, filed Oct. 20, 2003, and is related to U.S. patent application Ser. No. 10/575,754, filed Apr. 13, 2006.

### BACKGROUND OF THE INVENTION

The present invention relates to ferroelectric varactors, and in particular, to a ferroelectric varactor shunt switch that is suitable for microwave and millimeterwave applications.

Electrically tunable microwave filters have many applications in microwave systems. These applications include local multipoint distribution service (LMDS), personal communication systems (PCS), frequency hopping radio, satellite communications, and radar systems. There are three main kinds of microwave tunable filters, mechanically, magnetically, and electrically tunable filters. Mechanically tunable filters are usually tuned manually or by using a motor. They suffer from slow tuning speed and large size. A typical magnetically tunable filter is the YIG (Yttrium-Iron-Garnet) filter, which is perhaps the most popular tunable microwave filter, because of its multi-octave tuning range, and high selectivity. However, YIG filters have low tuning speed, complex structure, and complex control circuits, and are expensive.

One electronically tunable filter is the diode varactor-tuned filter, which has a high tuning speed, a simple structure, a simple control circuit, and low cost. Since the diode varactor is basically a semiconductor diode, diode varactor-tuned filters can be used in monolithic microwave integrated circuits (MMIC) or microwave integrated circuits. The performance of varactors is defined by the capacitance ratio, Cₘₐₓ/Cₘᵢₙ, frequency range, and figure of merit, or Q factor at the specified frequency range. The Q factors for semiconductor varactors for frequencies up to 2 GHz are usually very good. However, at frequencies above 2 GHz, the Q factors of these varactors degrade rapidly.

Since the Q factor of semiconductor diode varactors is low at high frequencies (for example, <20 at 20 GHz), the insertion loss of diode varactor-tuned filters is very high, especially at high frequencies (>5 GHz). Another problem associated with diode varactor-tuned filters is their low power handling capability. Since diode varactors are nonlinear devices, larger signals generate harmonics and subharmonics.

Varactors that utilize a thin film ferroelectric ceramic as a voltage tunable element in combination with a superconducting element have been described. For example, U.S. Pat. No. 5,640,042 discloses a thin film ferroelectric varactor having a carrier substrate layer, a high temperature superconducting layer deposited on the substrate, a thin film dielectric deposited on the metallic layer, and a plurality of metallic conductive means disposed on the thin film dielectric, which are placed in electrical contact with RF transmission lines in tuning devices. Another tunable capacitor using a ferroelectric element in combination with a superconducting element is disclosed in U.S. Pat. No. 5,721,194.

With the advent of microelectromechanical system (MEMS) technology, attention has been focused on the development of MEMS devices for radio frequency (RF) applications. MEMS switches are one of the most prominent micromachined products that have attracted numerous research efforts in recent years and have many potential applications such as impedance matching networks, filters, signal routing in RF system front-end and other high frequency reconfigurable circuits. MEMS switches provide many advantages over conventional electromechanical or solid-state counterparts in terms of low insertion loss, high isolation, low power consumption, high breakdown voltage, high linearity and high integration capability. The majority of today's MEMS switches employ electrostatic actuation and require a high actuation voltage, a major drawback of this type of switch. Recently, high relative dielectric constant Barium Strontium Titanium Oxide (BST) thin-films have been used in RF MEMS switches as a dielectric layer for reducing the actuation voltage requirements as well as improving isolation[ ]. Isolation can be improved more than 10 dB using ferroelectric thin-films of BST compared to dielectric materials such as Si₃N₄.

However, RF MEMS switches have several limitations such as, for example, relatively low speed, low power handling capability, required high actuation voltage, low reliability, low switching lifetime and high packaging cost. Although improvements are being made in these areas, challenges remain for commercial applications of RF MEMS switches. A ferroelectric varactor based capacitive shunt switch can overcome most of the limitations of existing RF MEMS switches.

### BRIEF SUMMARY OF THE INVENTION

It is against this background that the present invention is based on a coplanar waveguide (CPW) transmission line shunted by a ferroelectric varactor. The novelty in the implementation comes from the elimination of any moving parts for switching and from the elimination of via connections. High resistivity silicon with a SiO₂ layer and a metallic layer deposited on top is used as the substrate. The substrate can be any low-loss microwave substrate such as, for example, sapphire, magnesium oxide, lanthanum aluminate, etc. A ferroelectric thin-film layer is deposited on a patterned bottom metal layer (metal1 layer) for the implementation of the varactor. A top metal electrode (metal2 layer) is deposited on the ferroelectric thin-film layer, and patterned to form a CPW transmission line, such that an overlapping area of the center conductor of the CPW in metal1 and the shorting line in metal2 layers defines the varactor area. By using the large area ground planes in the metal2 layer as well as the metal1 layer, a series connection of the ferroelectric varactor with the large capacitor defined by the ground planes on the top and bottom metal layers was created. The large capacitor acts as a short to ground, eliminating the need for any vias. The concept of switching ON and OFF state is based on the dielectric tunability of the BST thin-films. At zero-bias, the varactor capacitance is high, resulting in the signal being shunted to ground (and reflected back), thus isolating the output from the input, resulting in the OFF state of the switch. At a dc bias less than 10 V, the varactor capacitance is reduced to a minimum, resulting in most of the signal transmitted to the output port, and thus the ON state.

Accordingly, it is a feature of the embodiments of the present invention to create a varactor shunt switch with improved isolation and insertion loss with reduced bias voltage.

It is another feature of the embodiments of the present invention to create a varactor shunt switch with lower bias voltage requirement, high switching speed, ease of fabrication and high switching lifetime.

It is yet another feature of the embodiments of the present invention to use a varactor shunt switch for passive sensing.

It is still another feature of the embodiments of the present invention to use a varactor shunt switch for wireless sensing.

Other features of the embodiments of the present invention will be apparent in light of the description of the invention embodied herein.

### BRIEF DESCRIPTION OF THE SEVERAL VIEWS OF THE DRAWINGS

The following detailed description of specific embodiments of the present invention can be best understood when read in conjunction with the following drawings, where like structure is indicated with like reference numerals and in which:

FIG. 1 illustrates a cross-sectional view of the multiple layers of the capacitive shunt switch according to one embodiment of the present invention.

FIG. 2a is a pattern of the bottom metal electrode according to one embodiment of the present invention.

FIG. 2b is a pattern of the top metal electrode according to one embodiment of the present invention.

FIG. 2c is a top-view of a varactor according to one embodiment of the present invention.

FIG. 2d is a cross-sectional view of the varactor area according to one embodiment of the present invention.

FIG. 3 illustrates a top view of the capacitive shunt switch according to one embodiment of the present invention.

FIG. 4 represents the electric circuit model of the varactor shunt switch of FIG. 3 according to one embodiment of the present invention.

FIG. 5 illustrates simulated isolation using different dielectric constants with the same varactor area according to one embodiment of the present invention.

FIG. 6 illustrates simulated insertion loss using different varactor areas with the same dielectric constant according to one embodiment of the present invention.

FIG. 7 illustrates simulated isolation and insertion loss of the varactor shunt switch for an optimized device according to one embodiment of the present invention.

FIG. 8 illustrates experimental measurements on the varactor shunt switch according to one embodiment of the present invention.

FIG. 9 illustrates experimental results versus the simulation results for the varactor shunt switch according to one embodiment of the present invention.

### DETAILED DESCRIPTION

In the following detailed description of the embodiments, reference is made to the accompanying drawings that form a part hereof, and in which are shown by way of illustration, and not by way of limitation, specific embodiments in which the invention may be practiced. It is to be understood that other embodiments may be utilized and that logical, mechanical and electrical changes may be made without departing from the spirit and scope of the present invention.

The concept of implementing shunt capacitance will be useful for a large number of MMICs such as, for example, tunable one-dimensional and two-dimensional electromagnetic bandgap (EBG) structures, tunable band-reject and bandpass filters, interference suppression systems, microwave switching applications, distributed phase shifters for microwave and millimeterwave frequencies. Furthermore, the present invention is also suitable for two-dimensional and three-dimensional EBG arrays. In addition, these switches could be used in analog and digital applications, such as, for example, interlayer coupling in multi-layered packages, isolation of specific subsystems with a larger system. This type of switch could also serve as a sensory element, since ferroelectric thin-films manifest piezo-electricity (useful for pressure sensors, accelerometers, etc.), pyroelectricity (for infra-red detectors), and electro-optic activity (voltage induced refractive index change for color filters, displays, optical switching, etc.).

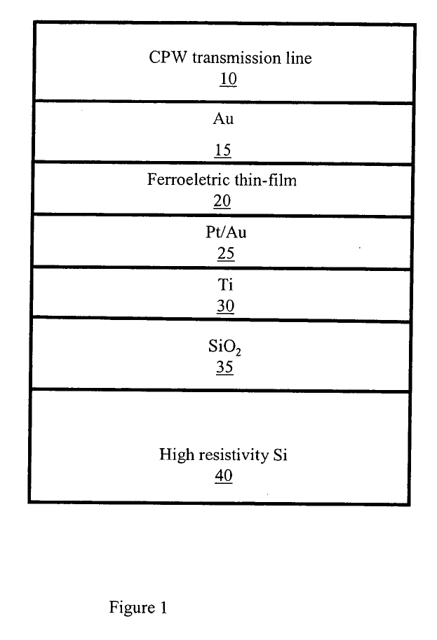

FIG. 1 illustrates a cross-sectional view of the multiple layers of the varactor shunt switch. The varactor shunt switch is designed on CPW transmission line 10 with a multilayer substrate. A tunable ferroelectrical thin-film of BST 20 with a high dielectric constant (εᵣ≧100) can be used as a dielectrical layer and may have a thickness of about 100-400 nm on top of a platinum/gold layer 25 which may have a thickness of about 500 nm. A titanium adhesion layer 30 of about 20 nm may be deposited between the platinum/gold layer 25 and the silicon oxide/high resistivity silicon substrate layer 35 and 40. The silicon can have resistivity of >1 kΩ-cm and is typically about 6 kΩ-cm. The thickness of the silicon oxide layer 35 and the high resistivity silicon substrate 40 can be about 200 nm and about 20 mils respectively.

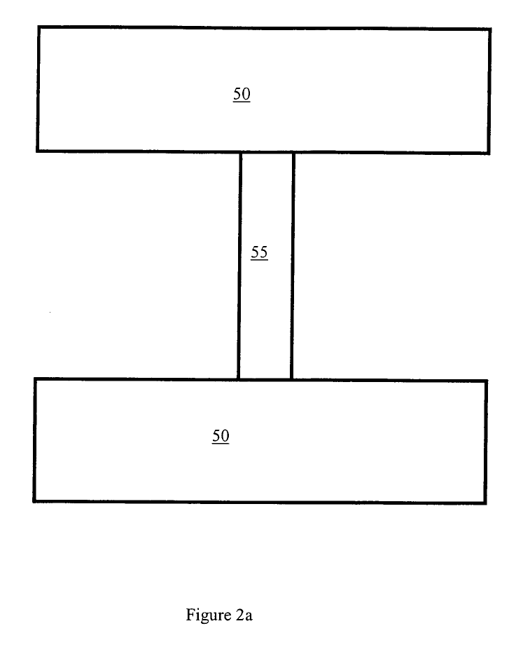

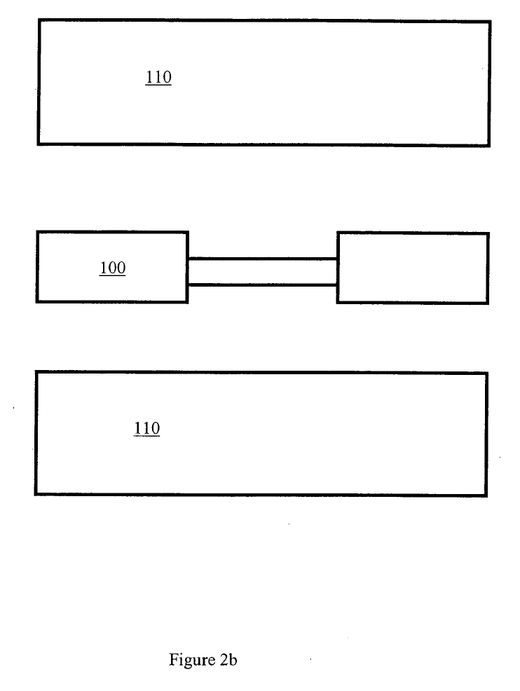

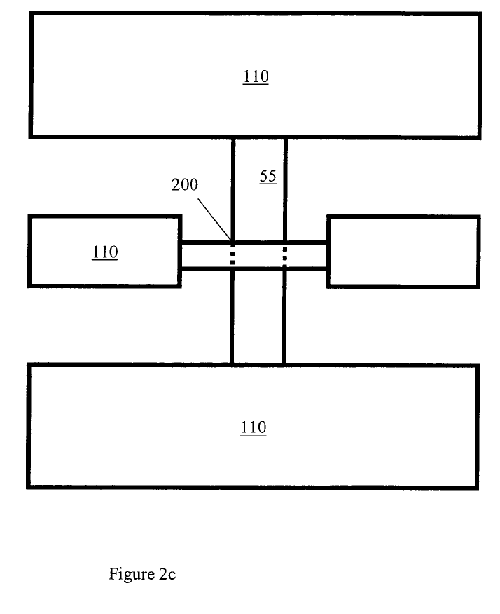

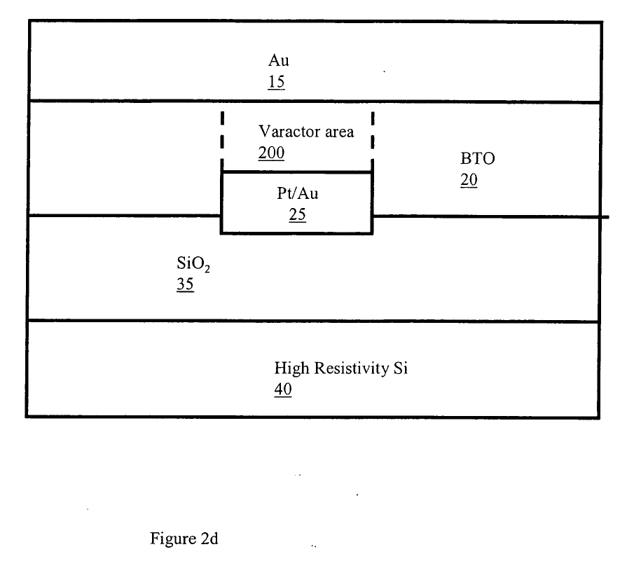

As a first step in the process, a patterned bottom electrode (metal1 layer) can be processed on the Si/SiO₂ substrate by electron-beam (e-beam) deposition (or sputtering) and lift-off photolithography technique. FIG. 2a illustrates the pattern of the bottom metallic layer 25. After the lift-off photolithography process for the platinum/gold layer 25, the layer 25 may be covered by a 100-400 nm ferroelectric thin film 20 such as, for example, barium strontium titanate (BST), strontium titanate (STO) or any other non-linear tunable dielectric, using a pulsed laser ablation (PLD) process or by RF sputtering. Note that the ferroelectric thin-film can be used in the paraelectric state or in the ferroelectric state to optimize the switch performance based on the type of application.

FIG. 2b illustrates the pattern of the top metal electrode 15 that can be deposited on top of the ferroelectric thin film 20. This top metal electrode 15 may be comprised of gold and includes the central signal strip 100 and the ground conductors 110 of the CPW. The top metal electrode 15 may be prepared by e-beam deposition (or sputtering) and lift off photolithography process. The ground conductors 50 in the bottom metallic layer 25 and top metal electrode 15 are effectively shorted, due to the large capacitance between these two layers, eliminating need for the via holes.

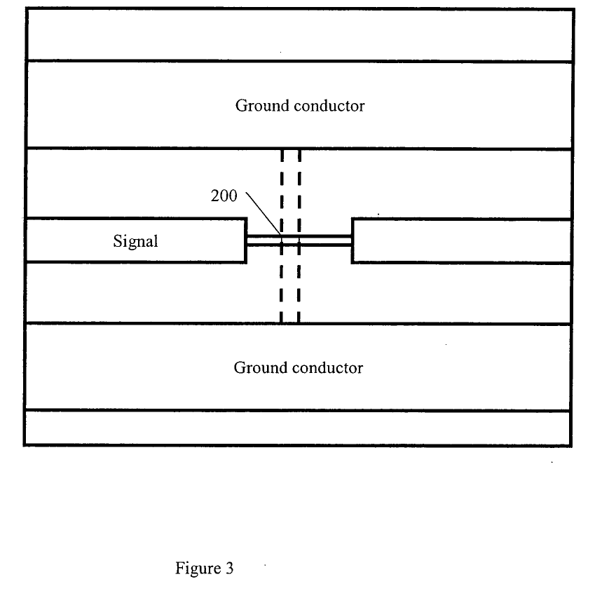

The top view of the finalized CPW is shown in FIG. 2c. In FIG. 2c, the varactor area 200 is defined by the overlap area between the top metal electrode 15 and the bottom metallic layer 25 as indicated by the dashed lines. The two ground conductors 50 of the bottom metallic layer 20 have exactly the same dimensions as the CPW ground lines 110 of the top metal electrode 15. A shunt conductor 55 connects the two ground lines 50 in the metal1 layer. The varactor area 200 is formed by the overlap of the shunt conductor 55 of the bottom metallic layer 25 and the central signal strip 100 of the top metal electrode 15 as illustrated by the dotted lines in FIG. 3.

When the capacitance of the varactor is very high (at 0V bias), the signal is coupled through the varactor and passes through the shunt conductor 55 to the ground. The varactor capacitance is in series with the larger capacitance introduced by the overlapping of the ground conductors 50, 110 in the top metal electrode (metal2) 15 and the bottom metallic layer (metal1) 25. The output is isolated from the input because of the signal being shunted to ground at 0V, resulting in the OFF state of the device. When a DC voltage is applied to the center conductor 100 of the CPW in the metal2 layer 15, the dielectric constant of the ferroelectric thin-film 20 is reduced and results in a lower varactor capacitance. When the varactor capacitance becomes small, the majority of signal from the input will be passed on to the output, because of reduced coupling by the varactor, resulting in the ON state of the device. Large dielectric tunability results in high isolation and low insertion loss of the device.

In the cross section of the varactor, see FIG. 2d, the widths of the two overlapping ground lines 100 of the top metal electrode 15 and the ground lines 50 of the bottom metallic layer 25 are chosen such that a required value of capacitance is obtained based on the known relative permittivity (εᵣ) of the ferroelectric thin-film 20. Tuning is obtained if a DC electric field is applied between the ground conductors 100 and the central signal strip 110 of the CPW (using CPW probes). The DC field changes the relative permittivity of ferroelectric thin-film 20, and hence the capacitance of the varactor. Since the varactor is in series with the large ground pad capacitor, the shunt conductances of the varactor and the ground pad capacitor creates a path for the dc current flow, and hence eliminates the need for via-connection to the ground line in metal 1. Also, the ground pad capacitor being a much larger than the varactor, presents a high conductance across the capacitor, resulting in most of the applied dc bias to be dropped across the varactor itself. A dc bias less than 10 V is needed to switch the device to the ON state. Note that the device is normally OFF, and is turned ON once a dc bias is applied.

In one embodiment, the width of the center signal strip 110 of the CPW and the spacing between the center signal strip 110 and ground conductors 100 were chosen so that the characteristic impedance is close to about 50Ω and the line losses are minimized. The CPW line has the dimensions of Ground-Signal-Ground being 50 μm/50 μm/50 μm for DC-20 GHz on the high resistivity silicon substrate 35. The spacing (S) between the center signal strip 110 and ground conductors 100 is taken as 50 μm and the geometric ration (k=W/(W+2S)) is equal to 0.333 of the CPW line. The device area is approximately 450 μm by 500 μm. The varactor area 200, which is the overlap of the top metal electrode 15 and the bottom metallic layer 25 is approximately 75 μm².

The simple circuit implementation as the present invention is compatible with Si MMIC technology, wherein the need for vias is eliminated in this two metal layer process. The switch is in the normally “OFF” state compared to MEMS capacitive shunt switches which are in the normally “ON” state. In addition, these switches are capable of switching at ˜30 ns switching speeds, where as the MEMS switches are slower (−10 μs). Further, a lower bias voltage (<10V) can be used compared to MEMS (40-50V) for switching. The varactor shunt switch can be designed for a bias voltage of less than 2 V.

The design trade between the isolation (OFF-state) and insertion (ON-state) loss depends on the varactor area 200 and the dielectric constant of the BST thin-films 20. Large varactor area and high dielectric constant are required to get the high isolation but it will increase the insertion loss. To keep the insertion loss at a minimum (<1 dB), the optimized overlapping area 200 and dielectric constant are taken as 25 μm² and 1200 respectively.

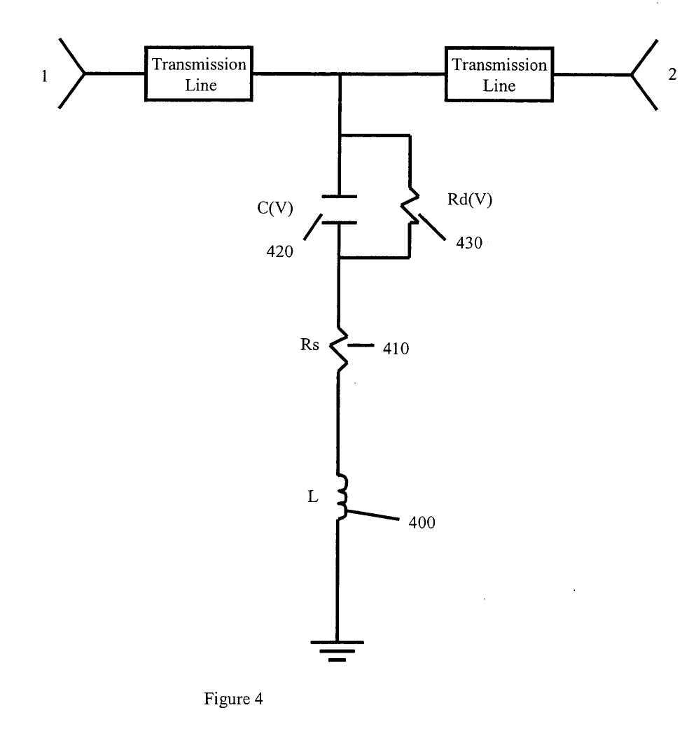

FIG. 4 represents the electric circuit model of the varactor shunt switch of FIG. 3. The electrical circuit model is obtained by shunting the varactor, with L 400 and Rs 410 being parasitic inductance and resistance respectively. The shunt resistance Rd 430 models the lossy (leakage conductance) nature of the varactor. The varactor capacitance 420 can be obtained by the standard parallel plate capacitance calculation, with the dielectric permittivity of the ferroelectric thin-film 20, and the overlap area 200 of the center signal strip 110 and the shunt line 55. The varactor capacitance is given by:
Cv=ε₀.ε_{rf}.At (1)
where ε₀ is the dielectric permittivity of free space, ε_{rf} is the relative dielectric constant of the ferroelectric thin-film 20 used, A is the area of the varactor, and t is the thickness of the ferroelectric thin-film 20.

The series resistance (Rs) 410 of the shunt conductor 55 in the bottom metal layer (metal1) 25, where the signal is shunted to ground is calculated using Equation 2
R=l/(σwt) (2)
where, σ is the conductivity of metal used in the top metal electrode 15, w is the width of the conductor, l is the length of the line shunting to ground, and t is the thickness of the conductor.

The inductance 400 (L) of the line is calculated using Equation (3)
L=(Z₀/(2πf)sin(2πl/λ_{g}) (3)
where, Z₀ is the characteristic impedance of the CPW transmission line, f is the operating frequency, and λ_{g} is the guide-wavelength.

The shunt resistance 430 (Rd) of the varactor can be calculated using Equation (4)
Rd(V)=1/(ωC(V)tan δ) (4)
where, C(V) 420 is the capacitance of the varactor and tan δ is the loss-tangent of the ferroelectric thin-film 20.

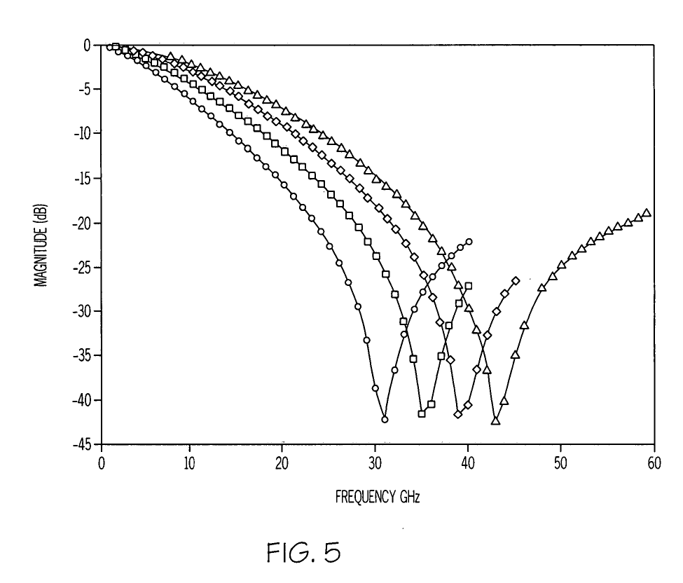

The performance (e.g., high isolation, low insertion loss, etc.) of the capacitive shunt switch depends on the dielectric tunability of the ferroelectric thin-film. High capacitance value will increase the isolation in the OFF-state but it will also increase the insertion loss in the ON-state. The capacitance value can be increased by using a high dielectric constant of the ferroelectric thin-films or large varactor area. Increasing the dielectric constant of the ferroelectric thin-films with same varactor area does not change the isolation very much but the resonance frequency decreases due to the increased varactor capacitance, see FIG. 5. FIG. 5 shows the isolation for the relative dielectric constants of 2000, 1500, 1200 and 1000 from left to right with a fixed varactor area of 5×5 μm².

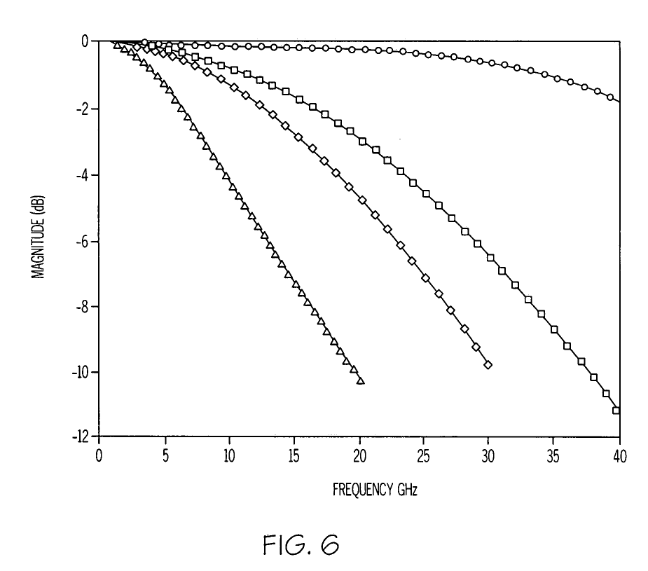

Further, insertion losses increase with increasing varactor area as shown in FIG. 6. FIG. 6 illustrates the insertion loss for a fixed dielectric constant of value 200 with the varactor areas of 15×15 μm², 10×10 μm², 10×5 μm², and 5×5 μm² from left to right.

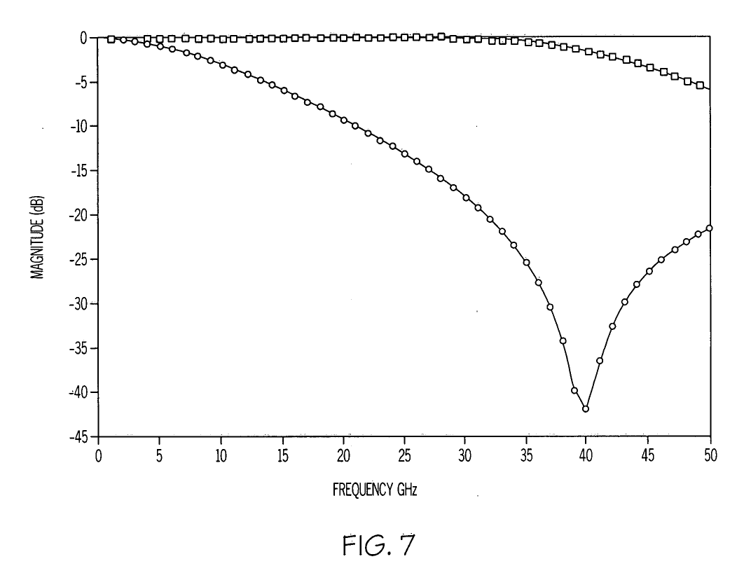

The simulated optimized dielectric constant of ferroelectric thin-films is taken as 1200 for the OFF-state and 200 for the ON-state with a varactor area of 5×5 μm², or 25 μm². FIG. 7 illustrates the simulated isolation and insertion loss of the varactor shunt switch for the optimized device. The isolation of the device is better than 30 dB at 30 GHz and the insertion loss is below 1 dB below 30 GHz.

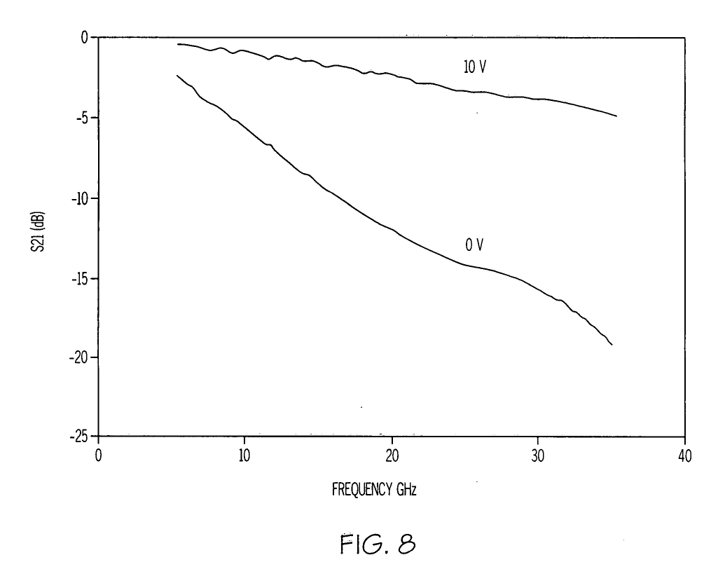

The varactor shunt switch was tested using a HP 8510 Vector Network Analyzer (VNA). A Line-Reflect-Reflect-Match (LRRM) calibration was performed over a wide frequency range (5 to 35 GHz). The sample was then probed using standard GSG probes. The dc bias was applied through the bias tee of the VNA. FIG. 8 illustrates the experimental measurements performed on the varactor shunt switch for 0 V (i.e., the OFF state) and for 10 V dc bias (i.e., the ON state). In the measured device, the capacitance of the varactor at zero bias was about 0.85 pF and was reduced to about 0.25 pF for a bias voltage of 10 V, thereby, resulting in a dielectric tunability of more than 3:1.

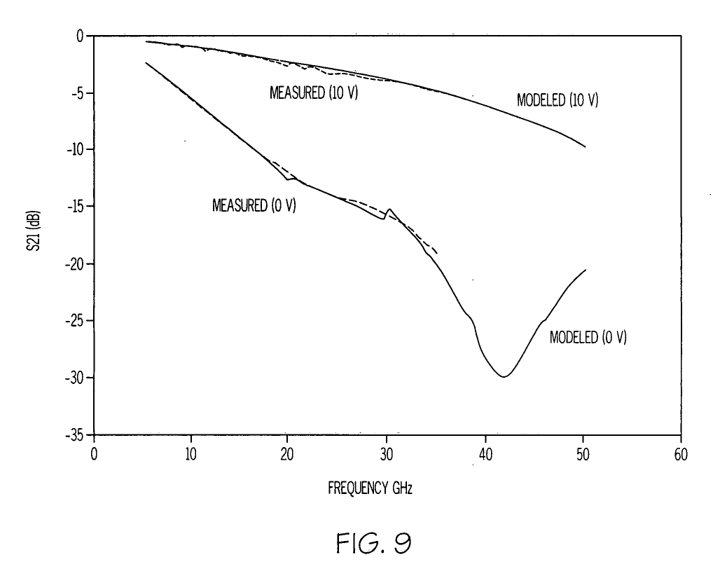

FIG. 9 illustrates the experimental results obtained from the varactor shunt switch compared to the simulation results based on the electrical model developed for the device. The experimental results were obtained up to 35 GHz. Theoretical simulations performed on the same device indicates that the isolation (off-state S21) improves to 30 dB near 41 GHz. A good agreement between the theoretical and experimental results over the frequency range of measurements can be seen as shown in FIG. 9. Therefore, the experimental data confirms the operation of the varactor shunt switch for microwave switching applications.

Table 1 demonstrates the comparison among solid-state switching devices, RF MEMS and the ferroelectric-based varactor shunt switch. The advantages of the varactor shunt switch include lower bias voltage requirement, high switching speed, ease of fabrication and high switching lifetime.

TABLE 1

| Device | | | |
|---|---|---|---|
| characteristics | | RF MEMS | Ferroelectric |
| and performance | Solid state | capacitive shunt | varactor based |
| parameter | switches | switches | shunt switch |
| Type of switch | Normally OFF or | Normally ON | Normally OFF |
| | ON | | |
| Actuation voltage | Low (3-8 V) | High (40-50 V) | Low (<10 V) |
| Switching speed | High (5-100 ns) | Low (˜10 μs) | High (<100 ns) |
| Isolation (dB) | <20 db @ 20 GHz | Very high (>40 dB | High (>20 dB @ 30 GHz) |
| | | @ 30 GHz) | |
| Insertion loss (dB) | >1 db @ 30 GHz | Very low (<1 dB @ | Low (<1.5 dB @ 30 GHz) |
| | | 30 GHz) | |
| Switching lifetime | High | Low | High |
| Packaging cost | Low | High | Low |
| Power handling | Poor (0.5-1 W) | Medium (<5 W) | Medium (<5 W) |
| Power consumption | Low (1-20 mW) | Almost zero | Almost zero |
| (OFF-state) | | | |
| Breakdown voltage | Low | High | <20 V |
| DC resistance | High (1-5 Ω) | Low (<0.5 Ω) | Low (<0.5 Ω) |
| Linearity | Low | High | High |
| IP3 | Low (˜+28 dBm) | High (˜+55 dBm) | Not available |
| Integration | Very good | Very good | Very good |
| capability | | | |

Note that the ferroelectric varactor shunt switch performance predicted in the table are based on theoretical calculations.

Note that the ferroelectric varactor shunt switch performance predicted in the table are based on theoretical calculations.

In another embodiment, the varactor shunt switch can act as a passive sensor. Directed energy in the form of radio frequency, ultra violet or infrared energies will change the capacitance of the varactor shunt switch. In one embodiment, the top metal electrode will be perforated. Therefore, any change to the surface potential due to the sensing function will change the capacitance of the varactor shunt switch. Additionally, a chemical or biochemical sensor is possible by changing the ferroelectric film with a known functionalized polymer that can be spin coated on the varactor shunt switch. In the presence of a chemical or biochemical agent, a chemical or biochemical reaction can produce a change in surface potential of the top metal electrode. Additionally, in the presence of different chemicals, the conductivity of a functionalized polymer between the center conductor and the ground lines of the varactor shunt switch will change. The functionalized polymer's conductance change with the sensing of a chemical or biochemical agent will, in turn, significantly affect the ratio of reflected power to input power of the device.

In addition, an antenna may be integrated with the varactor shunt switch. With the integrated antenna, wireless interrogation of each sensor is possible. Then, these sensors can be truly zero-power sensors as they would not require any DC voltage or power for their operation. With each sensor integrated with a different frequency antenna, a continuous wave frequency modulated (CWFM) radar for wireless interrogation and sensing can be used. The sensors would be powered by the RF signal from the radar and will reflect the RF signal back to the radar. Because each sensor is different based on impedance changes, each sensor will absorb different parts of the spectrum. A large number of sensors can be fabricated on a single chip resulting in considerable sensitivity to change.

In another embodiment, as mentioned above, due to the piezoelectric property of the ferroelectric film, force or pressure changes can be measured. For example, the varactor shunt switch can be used to detect explosions occurring in the vicinity of the varactor shunt switch. In addition, the varactor shunt switch can also be used as an accelerometer by measuring changes in the varactor shunt switch piezoelectricity.

It is noted that terms like “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A passive sensor, the passive sensor comprising:
a varactor shunt switch, wherein said varactor shunt switch comprises:
a substrate;
a patterned bottom metal layer deposited on said substrate;
a ferroelectric thin film is deposited on said patterned bottom metal layer; and
a top metal electrode deposited on said ferroelectric thin film, wherein said top metal electrode is patterned to form a coplanar waveguide transmission line and wherein the surface potential of said top metal electrode changes in the presence of a form of directed energy,
wherein the capacitance of said varactor shunt switch will change in response to changes of said surface potential.

2. The passive sensor of claim 1, wherein said form of directed energy comprises radio frequency, ultra violet energy, infrared energy, and combinations thereof.

3. The passive sensor of claim 1, wherein said top metal electrode is perforated.

4. The passive sensor of claim 1, wherein a large number of said passive sensors can be fabricated on a single chip.

5. The passive sensor of claim 1, further comprising:
an antenna integrated with said varactor shunt switch for wireless interrogation.

6. A passive sensor, the passive sensor comprising:
a varactor shunt switch, wherein said varactor shunt switch comprises:
a substrate;
a patterned bottom metal layer deposited on said substrate;
a functionalized polymer thin film is spin coated on said patterned bottom metal layer; and
a top metal electrode deposited on said functionalized polymer thin film, wherein said top metal electrode is patterned to form a coplanar waveguide transmission line and wherein the surface potential of said top metal electrode changes in the presence of a chemical or biochemical agent due to a chemical reaction with said functionalized polymer thin film,
wherein the capacitance of said varactor shunt switch will change in response to changes of said surface potential.

7. The passive sensor of claim 6, wherein the conductivity of a functionalized layer coated between the center conductor and the ground lines of said varactor shunt switch will change in said presence of said chemical or biochemical agent.

8. The passive sensor of claim 7, wherein the conductance change of said varactor shunt switch in said presence of said chemical or biochemical agent will affect the ratio of reflected power to input power of said varactor shunt switch.

9. The passive sensor of claim 6, further comprising:
an antenna integrated with said varactor shunt switch for wireless interrogation.

10. A passive piezoelectric sensor, the passive piezoelectric sensor comprising:
a varactor shunt switch, wherein said varactor shunt switch comprises:
a substrate;
a patterned bottom metal layer deposited on said substrate;
a ferroelectric thin film is deposited on said patterned bottom metal layer; and
a top metal electrode deposited on said ferroelectric thin film, wherein said top metal electrode is patterned to form a coplanar waveguide transmission line.
wherein said varactor shunt switch is responsive to changes in pressure or force due to the piezoelectric property of said ferroelectric thin film.

11. The passive sensor of claim 10, wherein said varactor shunt switch can be used as accelerometer.

12. A passive sensor, the passive sensor comprising:
a varactor shunt switch, wherein said varactor shunt switch comprises:
a substrate;
a patterned bottom metal layer deposited on said substrate;
a thin film is deposited on said patterned bottom metal layer; and
a top metal electrode deposited on said thin film, wherein said top metal electrode is patterned to form a coplanar waveguide transmission line,
wherein the capacitance of said varactor shunt switch will change in response to changes of surface potential of said top metal electrode; and
an antenna integrated with said varactor shunt switch, wherein said antenna is responsive to a radio frequency signal sent by a radar.

13. The passive sensor of claim 12, wherein said radar is a continuous wave frequency modulated radar.

14. The passive sensor of claim 12, wherein said passive sensor is powered by said radio frequency signal from said radar.

15. The passive sensor of claim 12, wherein said passive sensor reflects said radio frequency signal back to said radar.

16. The passive sensor of claim 12, wherein a large number of said passive sensors can be fabricated on a single chip.

17. The passive sensor of claim 16, wherein each antenna of each passive sensor of said large number of said passive sensors comprises a different frequency antenna resulting in different impendence changes for each passive sensor in said large number of said passive sensors.

18. The passive sensor of claim 17, wherein each passive sensor of said large number of said passive sensors will absorb different parts of the spectrum.

19. A method of passive sensing, the method comprising:
depositing an adhesion layer on a substrate;
depositing a pattern bottom metal layer on said adhesion layer;
covering said pattern bottom metal layer with a layer of thin film, wherein said pattern bottom metal layer comprises of at least two ground conductors and a shunt conductor;
topping said layer of thin film with a top metal electrode, wherein said top metal electrode comprises of at least two ground conductors and a center signal strip; and
sensing changes in capacitance due to changes in surface potential of said top metal electrode.

20. The method of claim 19, wherein said thin film comprises a ferroelectric.

21. The method of claim 20, wherein said changes in surface potential of said top metal electrode result from directed energy.

22. The method of claim 19, wherein said thin film comprises a functionalized polymer.

23. The method of claim 22, wherein said changes in surface potential of said top metal electrode result from the presence of a chemical or biochemical agent.

24. The method of claim 23, further comprising:
sensing changes in conductiveness in response to said presence of said chemical or biochemical agent.

25. The method of claim 19, further comprising:
integrating an antenna, wherein said antenna is responsive to a radio frequency signal sent by a radar.

26. A method of passive wireless sensing, the method comprising:
depositing an adhesion layer on a substrate;
depositing a pattern bottom metal layer on said adhesion layer;
covering said pattern bottom metal layer with a layer of thin film, wherein said pattern bottom metal layer comprises of at least two ground conductors and a shunt conductor;
topping said layer of thin film with a top metal electrode, wherein said top metal electrode comprises of at least two ground conductors and a center signal strip; and
integrating an antenna, wherein said antenna is responsive to a radio frequency signal sent by a radar.

27. The method of passively wireless sensing of claim 26, wherein said radar is a continuous wave frequency modulated radar.

28. The method of passively wireless sensing of claim 26, wherein said passively wireless sensing is powered by said radio frequency signal sent by said radar.

29. The method of passively wireless sensing of claim 26, further comprising:
reflecting said radio frequency signal back to said radar.

30. A passive sensor, the passive sensor comprising:
a varactor shunt switch, wherein said varactor shunt switch comprises:
a substrate;
a patterned bottom metal layer deposited on said substrate;
a ferroelectric thin film is deposited on said patterned bottom metal layer; and
a top metal electrode deposited on said ferroelectric thin film, wherein said top metal electrode is patterned to form a coplanar waveguide transmission line;
wherein changes in capacitance of said varactor shunt switch resulting from external stimuli are monitored.

31. The passive sensor of claim 30, further comprising:
an antenna integrated with said varactor shunt switch for wireless interrogation.

32. A passive sensor, the passive sensor comprising:
a varactor shunt switch, wherein said varactor shunt switch comprises:
a substrate;
a patterned bottom metal layer deposited on said substrate;
a ferroelectric thin film deposited on said patterned bottom metal layer; and
a top metal electrode deposited on said ferroelectric thin film, wherein said top metal electrode is patterned to form a coplanar waveguide transmission line.
wherein the output of said varactor shunt switch is responsive to changes in capacitance and wherein said changes in capacitance and output are monitored.

33. A passive sensor, the passive sensor comprising:
a varactor shunt switch, wherein said varactor shunt switch comprises:
a substrate;
a patterned bottom metal layer deposited on said substrate;
a thin film is deposited on said patterned bottom metal layer; and
a top metal electrode deposited on said thin film, wherein said top metal electrode is patterned to form a coplanar waveguide transmission line,
wherein the capacitance of said varactor shunt switch will change in response to changes of surface potential of said top metal electrode due to external stimuli and wherein the output of said varactor shunt switch will change in response to the changes of capacitance.

34. A method of passive sensing, the method comprising:
depositing an adhesion layer on a substrate;
depositing a pattern bottom metal layer on said adhesion layer;
covering said pattern bottom metal layer with a layer of thin film, wherein said pattern bottom metal layer comprises of at least two ground conductors and a shunt conductor;
topping said layer of thin film with a top metal electrode, wherein said top metal electrode comprises of at least two ground conductors and a center signal strip; and
sensing changes in capacitance due to changes in surface potential of said top metal electrode resulting from external stimuli.

35. The method of claim 34, further comprising:
integrating an antenna, wherein said antenna is responsive to a radio frequency signal sent by a radar.

36. A method of passive sensing, the method comprising:
depositing an adhesion layer on a substrate;
depositing a pattern bottom metal layer on said adhesion layer;
covering said pattern bottom metal layer with a layer of thin film, wherein said pattern bottom metal layer comprises of at least two ground conductors and a shunt conductor;
topping said layer of thin film with a top metal electrode, wherein said top metal electrode comprises of at least two ground conductors and a center signal strip;
sensing changes in capacitance due to changes in surface potential of said top metal electrode resulting from external stimuli; and
monitoring changes in output due to the changes in capacitance.
